(19) United States
(12) Patent Application Publication
(10) Pub. No.: US 2007/0168845 A1
(43) Pub. Date: Jul. 19, 2007

(54) VITERBI DECODER

(75) Inventors: Akira ENDO, Yokohama (JP); Yuzo Nagai, Yokohama (JP); Takeshi Inoue, Yokohama (JP); Toshihiko Nawa, Yokohama (JP); Keitaro Otsuka, Yokohama (JP); Hitoshi Ando, Yokohama (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/278,698

(22) Filed: Apr. 5, 2006

(30) Foreign Application Priority Data
Dec. 26, 2005 (JP) 2005-372794

(51) Int. Cl. H03M 13/03

(52) U.S. Cl. 714/795

(57) ABSTRACT

In the present invention, the most likely transition source state bits are selected according to the path metric of the state bits corresponding to the state bits that could be taken for the encoded bits to be input, and are stored in the survival path memory. Therefore in the trace back processing, the decoded bits can be output only by repeating the extraction of the most significant bit of the transition source state bits. As a consequence, trace back processing can be performed very simply, and decoding processing becomes possible in a short time even if a general purpose processor executes the software.

### CROSS-REFERENCE TO RELATED APPLICATIONS

This application is based upon and claims the benefit of priority from the prior Japanese Patent Application No. 2005-372794, filed on Dec. 26, 2005, the entire contents of which are incorporated herein by reference.

### BACKGROUND OF THE INVENTION

1. Field of the Invention

The present invention relates to a viterbi decoder, and more particularly to a viterbi decoder of which decoding processing by software is simplified.

2. Description of the Related Art

The viterbi decoding method is one of the maximum likelihood decoding methods (a decoding method for estimating and outputting transmission codes that are most probable for receive codes), that can decode convolutional codes and has high error correction capability against transmission data errors which occur on a transmission path. Therefore a viterbi decoding method is used as an error correction technology for correcting the code errors of transmission data which occur on a transmission path, in order to increase the reliability of data transmission in the radio communication field, for example.

The transmission side encodes the transmission data by a convolutional encoder, and sends the encoded bits onto the transmission path. The receive side performs viterbi decoding to the received encoded bits so as to decode them into the original transmission data. The viterbi decoder performs trace back processing to reproduce the transmission data based on the distance between the received encoded bits and the encoded bits generated along with the possible transition of the state of the transmission data (hamming distance, metric). In order to enable this trace back processing, the viterbi decoder determines the above mentioned metric for the received encoded bits, and constructs survival path memory for storing the selected path information based on that. And after completing the reception of encoded bits for a predetermined data length, the viterbi decoder traces back the transmission data based on the selected path information of the survival path memory, and decodes and outputs the transmission data.

Such a viterbi decoder is disclosed in Japanese Patent Application Laid-Open No. H5-315976, for example.

This patent document (Japanese Patent Application Laid-Open No. H5-315976) discloses a viterbi decoder for performing maximum likelihood decoding convolutional codes with encoding ratio R=k/n and constraint length K, which encodes k-bit information into n-bit (n>k) codes, by using a path memory, wherein a path memory, for storing at least N words (N is K-kth power of 2) which is the same as the number of states according to the state transition information, is installed, partial k-bits of the selected state number (binary) are additionally stored at the LSB side for update while shifting the contents of each word of this path memory to the MSB side, and decoded output is acquired from the overflow information by this shift processing of the path memory. In other words, the LSB of the transition source state bits is stored in the path memory, and the information series in the path memory (LSB of state number) is added to the LSB while shifting the state number to the MSB side when the trace back processing is performed, and decoding output is acquired from the information overflow by the shift processing.

Japanese Patent Application Laid-Open No. 2000-357971, No. 2000-196468 and No. 2004-153319 also disclose viterbi decoders.

Out of these, in the case of Japanese patent Application Laid-Open No. 2004-153319 in particular, trace back processing is not performed after calculating the path metrics for all the paths, but path selection is performed each time encoded bits are received, and a path select signal (this becomes decoded data) on the selected path is dynamically written to the row register of the path memory section. At this time, writing is controlled so that a series of path select signals, for the selected path, are contained in one row, the path select signal string on the selected path is read from the row register all at once at the final time, and is used as the decoded data.

### SUMMARY OF THE INVENTION

In the case of the viterbi decoder disclosed in Japanese Patent Application Laid-Open No. H5-315976, in the trace back processing for acquiring decoded output, the state number of the trace start is shifted to the MSB side, the information string in the bus memory is added to the LSB which became open by the shift, and information overflow by the shift processing is output as the decoded bit string. Therefore the viterbi decoder of this patent document stores only the LSB of the state number of the transition source in the path memory, which decreases the capacity of the path memory, but makes trace back processing complicated accordingly.

In the case of Japanese Patent Application Laid-Open No. 2004-153319, a path select signal, to be the decoded data, is generated each time encoded bits are received, so the path select signal generation process is complicated, and if the size of the data string to be transmitted is large, the burden of the path select signal generation processing becomes heavy.

With the foregoing in view, it is an object of the present invention to provide a viterbi decoder in which trace back processing is simplified.

To achieve the above object, a first aspect of the present invention provides a viterbi decoder for inputting encoded bits, which are convolutional-encoded from state bits having input bit and a preceding (K−1) number of input bits, and decoding the input bit string by most likelihood encoding of the encoded bits, having: a path memory generation processing unit which, for the encoded bits to be input, selects transition source state bits corresponding to predetermined state bits according to a path metric, and stores the transition source state bits in a survival path memory for each of a plurality of predetermined state bits that could be taken; and a trace back processing unit which, after storing the transition source state bits in the survival path memory for the encoded bits to be input ends for the length of the trace back, extracts the most significant bit of state bits to be a start point of trace back, repeats the extraction of the most significant bit of the transition source state bits in the survival path memory corresponding to the state bits of which the most significant bit has been extracted, and outputting the extracted most significant bits as a decoding result.

In the first aspect of the present invention, it is preferable that the viterbi decoder receives the encoded bits sequentially, the path memory generation processing unit stores the transition source state bits to the survival path memory each time the encoded bits are received, and the trace back processing unit performs trace back processing after encoded bits for the length of the trace back are received.

To achieve the above object, a second aspect of the present invention provides a viterbi decoding program for inputting encoded bits which are convolutional-encoded from state bits having input bit and a preceding (K−1) number of input bits, and decoding the input bit string by most likelihood encoding of the encoded bits, which causes a computer to construct: a path memory generation processing unit which, for the encoded bits to be input, selects transition source state bits corresponding to predetermined state bits according to a path metric, and stores the transition source state bits in a survival path memory for each of a plurality of predetermined state bits that could be taken; and a trace back processing unit which, after storing the transition source state bits in the survival path memory for the encoded bits to be input ends for the length of the trace back, extracts the most significant bit of state bits to be a start point of trace back, repeats the extraction of the most significant bit of the transition source state bits in the survival path memory corresponding to the state bits of which the most significant bit has been extracted, and outputting the extracted most significant bits as a decoding result.

According to the second aspect of the present invention, the most likely transition source state bits are selected according to the path metric of the state bits corresponding to the state bits that could be taken for the encoded bits to be input, and are stored in the survival path memory. Therefore in the trace back processing, the decoded bits can be output only by repeating the extraction of the most significant bit of the transition source state bits. As a consequence, trace back processing can be performed very simply, and decoding processing becomes possible in a short time even if a general purpose processor executes the software.

### BRIEF DESCRIPTION OF THE DRAWINGS

FIG. 1 is a diagram depicting an example of a convolutional encoder;

FIG. 2 is a table showing an example of encoding with respect to the change of input bits in the encoder in FIG. 1;

FIG. 3 is a diagram depicting an encoder and decoder according to the present embodiment;

FIG. 4 is a trellis diagram of the convolutional encoder in FIG. 3;

FIG. 5 is a diagram depicting a path metric in viterbi decoding;

FIG. 6 is a diagram depicting the decoding method according to Japanese Patent Application Laid-Open No. H5-315976;

FIG. 7 is a diagram depicting the trace back processing;

FIG. 8 is a diagram depicting the decoding method according to the present embodiment;

FIG. 9 is a diagram depicting the decoding method according to the present embodiment;

FIG. 10 is a diagram depicting the relationship between the processing modules and the memories of the viterbi decoder according to the present embodiment;

FIG. 11 is a flow chart depicting the processing of the path memory generation processing module;

FIG. 12 is a flow chart depicting the processing of the trace back processing;

FIG. 13 is a flow chart depicting the specific processing of the processing module of the viterbi decoder according to the present embodiment;

FIG. 14 is a flow chart depicting the specific processing of the processing module of the viterbi decoder according to the present embodiment;

FIG. 15 is a flow chart depicting the specific processing of the processing module of the viterbi decoder according to the present embodiment;

FIG. 16 is a diagram depicting an example of the path metric memory;

FIG. 17 is a diagram depicting an example of the survival memory;

FIG. 18 is a diagram depicting the merit of operation of the viterbi decoder according to the present embodiment; and

FIG. 19 is a diagram depicting another merit of the operation of the viterbi decoder according to the present embodiment.

### DESCRIPTION OF THE PREFERRED EMBODIMENTS

Embodiments of the present invention will now be described with reference to the drawings. The technical scope of the present invention, however, is not limited to these embodiments, but extends to the contents written in the Claims and the equivalents thereof.

[Convolutional Encoding and Viterbi Encoding]

The viterbi decoder is used for the maximum likelihood decoding method for convolutional code or so, and is used as a decoder in the transmission systems of satellite communication and mobile communication where transmission path errors easily occur, since the error correction capability is high. In viterbi decoding, the branch metric processing for determining the hammering distance (branch metric), that is the difference between the received encoded bits and expected encoded bits, and the path memory generation processing by add, compare and select processing (ACS), are repeated, and after these processings are repeated for the number of times of the number of state bits multiplied by trace back length, the trace back processing for decoding the data to the input data is performed in the end.

Now the basic issues of encoding processing for generating the convolutional codes of input bits and the viterbi decoding processing for decoding the encoded bits to original input bits will be briefly described.

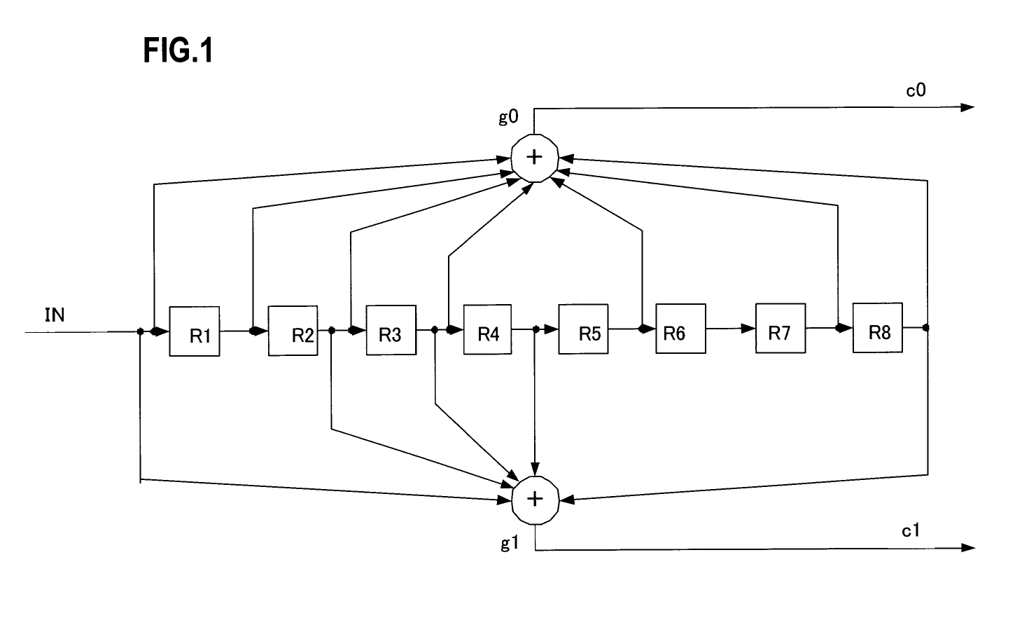

FIG. 1 is a diagram depicting an example of a convolutional encoder. The input bits IN are sequentially input to the registers R1 to R8 having a delay function, and the exclusive OR c0 of the input bits IN and the bits stored in the registers R1 to R8 and the exclusive OR c1 of the input bits IN and the bits stored in the registers R2, R3, R4 and R8 are generated by the exclusive OR circuits g0 and g1. The encoded bits c0 and c1 are “1” if the number of “1” of the corresponding input bits is an odd number, and “0” if it is an even number. When the encoded bits c0 and c1 are generated at the time of the input of input bits IN, the next input bits IN are input, and information of each register is shifted to the register of the subsequent step. In other words, encoding is performed each time the input bits IN are supplied, and a shift occurs among the registers. By this, the number of states comprised of the information bits of eight registers in the encoder to exist is the 8^{th} power of 2. The bit string to indicate this state is called “state bits” in the following description.

In this encoder, the number of registers is 8, and the two enclosed bits c0 and c1 are generated from one time of input bits IN, so the encoding ratio is rc=½ (encoding ratio when n-bits of encoded bits generated by k-bits of input bits is k/n), and one input bit IN and the preceding 8 input bits (R1 to R8) are encoded, so the number of input bits that influences encoding, that is constraint length K, is K=9.

The encoding ratio, which is a ratio of the input bits to the encoder and the output bits, generally decreases as the number of output bits, with respect to the input bits, increases, and the correction capability increases, although the transmission speed drops. Normally the encoding ratio is set to ½ in order to prevent a drop in the transmission speed. The constraint length K indicates the number of input bits in the past which are required to obtain encoded bit output, and the error correction capability increases as the constraint length increases, but in this case the number of state bits increases and the configuration of the viterbi decoder becomes complicated.

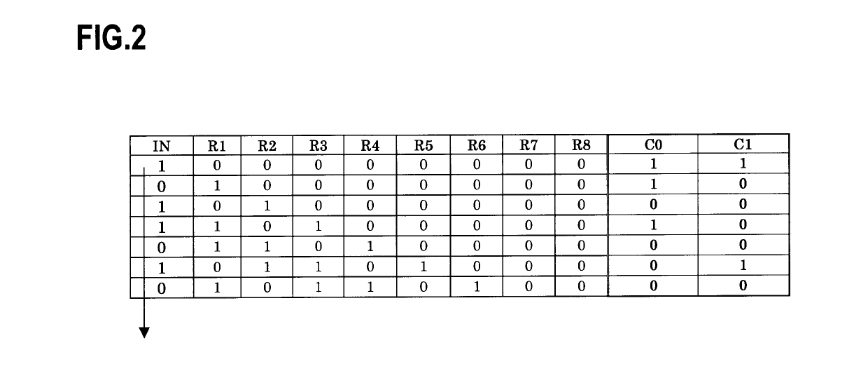

FIG. 2 is a table showing an example of encoding when the input bits IN is “1, 0, 1, 1, 0, 1, 0” in the encoder (K =9) in FIG. 1. It is assumed that the registers R1 to R8 have all been initialized to “0”. Each time the input bits IN are input, the state of the registers R1 to R8 changes, and the encoded bits c0 and c1 corresponding to each state are output.

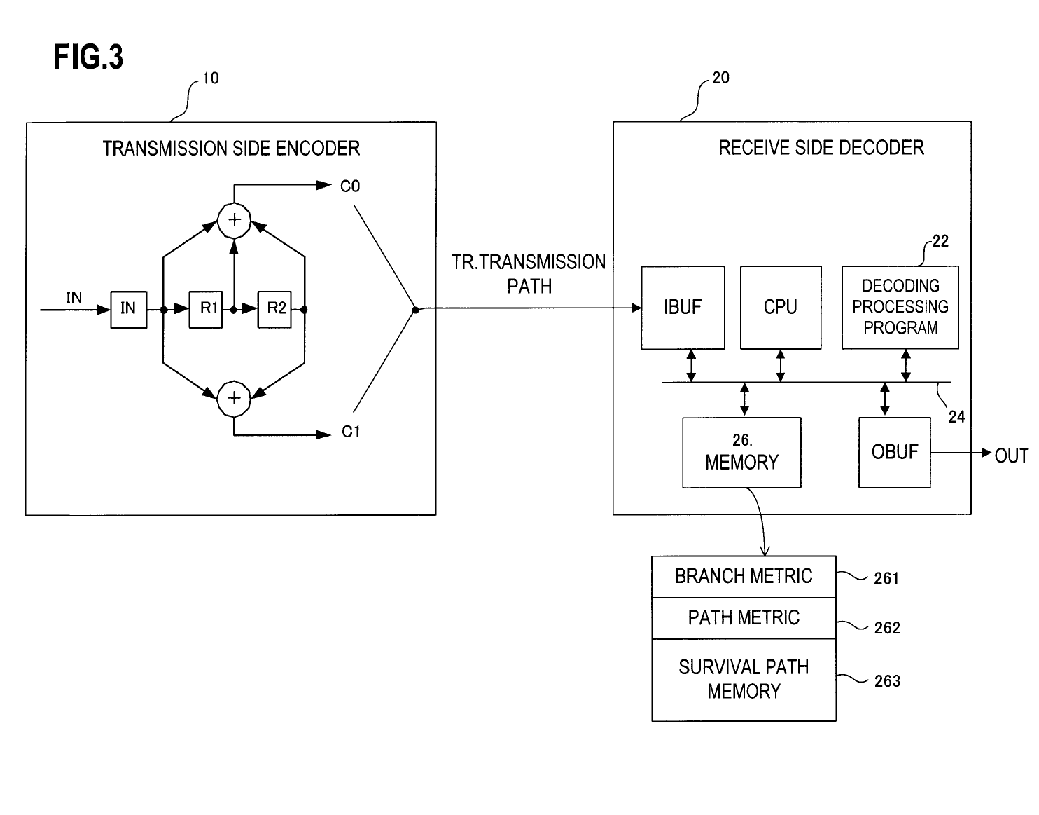

FIG. 3 is a diagram depicting the encoder and decoder according to the present embodiment. In the transmission side encoder 10, the encoded bits c0 and c1 are generated from the input bits IN and the input bits R1 and R2 in the past, and are transmitted via the transmission path TR. In this example, the encoder 10 has two registers R1 and R2 for simplification, and the constraint length K=3 and the encoding ratio is ½. Therefore the number of states by the registers in the encoder is (K−1)th power of 2. In the receive side decoder 20, the received encoded bits are loaded into the input buffer IBUF, and the central processing unit CPU executes the decoding processing program 22, by which the original input bits IN are decoded from the received encoded bits c0 and c1. This decoding is performed by the above mentioned maximum likelihood decoding method. And the decoded original input bits are output from the output buffer OBUF. In the decoder 20, the central processing unit CPU is connected to the memory 26 via the internal bus 24, and at the decoding processing, an area for storing the branch metrics 261 and the path metrics 262, and an area in the survival memory 163 for storing the selected path information, are secured in the memory 26. The branch metric, path metric and selected path information will be described later in detail.

Now the basic principle of the convolutional encoder and viterbi decoder will be described.

The viterbi decoding is a decoding method to decode convolutional-encoded information (encoded bits), wherein the most probable (maximum likelihood) transmission encoded bits are estimated at decoding, and original input bits are output from the state bits for generating the encoded bits. Now the trellis diagram to indicate the state transition of the convolutional encoder will be described first.

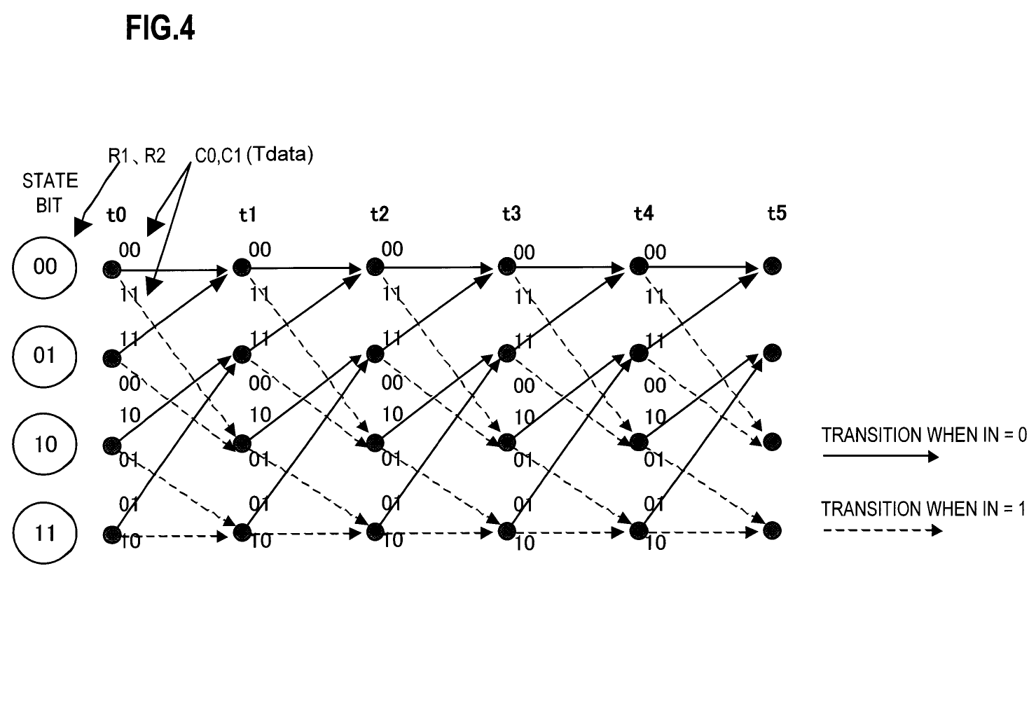

FIG. 4 is a trellis diagram in the convolutional encoder in FIG. 3. The convolutional encoder 10 in FIG. 3 has two registers R1 and R2, and the constraint length is K=3 and the encoding ratio is ½. Therefore the number of states of the two registers R1 and R2 are the b 2^{nd} power (K−1th power) of 2, that is 4. FIG. 4 shows the 4 state bits based on the combinations of the bits in the registers R1 and R2. For each of these 4 states, the state transition when the input bits IN are “0” is indicated by an arrow mark in a solid line, and the state transition when the input bits IN are “1” is indicated by an arrow mark in a broken line. These arrow marks are also called “branches”. In the horizontal direction the times t0 to t5 are shown, and the states at each time are indicated by black dots. And the encoded bits c0 and c1, which are generated with respect to the transition (arrow marks in solid line and broken line) from each state indicated by a black dot, are shown.

For example, in the case of state bits R1, R2=00 at time t0, when input bits IN=0 the encoded bits c0, c1=00 are generated, and the state moves to state bits 00 (arrow mark in solid line), and when the input bits IN=1 encoded bits c0, c1=11 are generated and the state moves to state bits=10 (arrow mark in broken line). In the same way, in the case of state bits R1, R2=01 at time t0, when the input bits IN=0 encoded bits c0, c1=11 are generated and the state moves to state bits=00 (arrow mark in solid line), and when the input bits IN=1 encoded bits c0, c1=00 are generated and the state moves to state bits=10 (arrow mark in broken line). In the case of the state bits R1, R2=10, when input bits IN=0 the encoded bits c0, c1=10 are generated and the state moves to the state bits=01 (arrow mark in solid line), and when the input bits IN=1 encoded bits c0, c1=01 are generated and the state moves to the state bits=11 (arrow mark in broken line). Finally in the case of state bits R1, R2=11, when the input bits IN=0 the encoded bits c0, c1=01 are generated and the state moves to the state bit=01 (arrow mark in solid line), and when the input bits IN=1 encoded bits c0, c1=10 are generated and the state moves to state bits=11 (arrow mark in broken line).

The above mentioned state transition and the encoded bits c0 and c1 generated accordingly are the same at any time of t0 to t4. Generally the state bits move upward when the input bits IN=0, and the state bits move downward when the input bits IN=1.

According to the above trellis diagram, the decoder at the receive side can reverse-trace the transition of state bits based on the encoded bits c0 and c1 to be received. If the transition of the state bits can be reverse-traced, the input bits IN which caused the transition to the state bits can be known, so decoding to the original input bits IN is possible. However all the encoded bits to be received are not always correct since an error may occur to the transmission path. Therefore in order to select the state bits at the transition source, the metric which is the hammering distance (difference) between the received encoded bits c0 and c1 and the transmitted encoded bits c0 and c1 corresponding to the branch (path) of the trellis is used. In other words, the most probable (maximum likelihood) state transition can be estimated by regarding that the state moved to the side of which this metric is smaller.

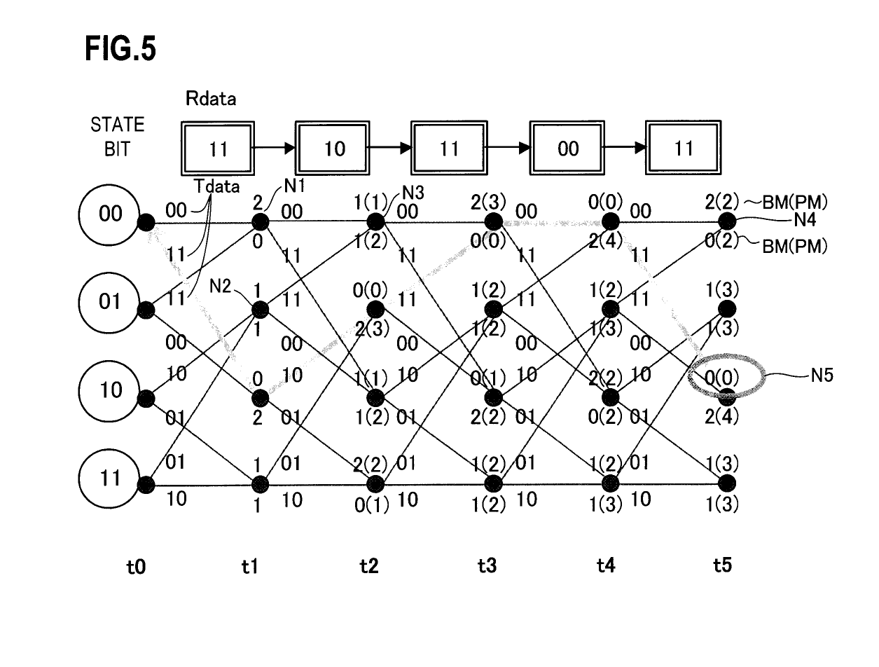

FIG. 5 is a diagram depicting the path metric in viterbi decoding. Just like the above mentioned trellis diagram, two transitions for the input bits IN=0 and 1, corresponding to the four state bits respectively, are shown. And in the branches (arrow marks in the trellis diagram in FIG. 4) that indicate two transitions, encoded bits to be generated are shown respectively. The encoded bits are encoded bits Tdata transmitted from the transmission side. FIG. 5 shows an example of the encoded bits Rdata to be received at the receive side.

The hammering distance between the transmitted encoded bits Tdata, which are expected encoded bits, and the received encoded bits Rdata can be calculated as a branch metric BM. The hamming distance is the difference of the number of bits between two bit strings, and in the case of 11 and 11 for example, which is a perfect match, the hamming distance is 0, and in the case of 11 and 10, of which difference is 1 bit, the hamming distance is 1, and in the case of 11 and 00, of which difference is 2 bits, the hamming distance is 2.

At the top and bottom of the node N1 of the state bits 00 at time t1, the branch metrics BM “2” and “0”, which are the hamming distances between the transmitted encoded bits Tdata and received encoded bits Rdata when moving to this state bit, are shown. In other words, the hamming distances of the received encoded bits Rdata=11 and the transmitted encoded bits Tdata=00 and 11 of the two branches that could transit to the node N1 are 2 and 0 respectively. Therefore it is judged that the transmitted encoded bits Tdata transmitted at transition to the node N1 (state bits 00, time t1) is most likely the one of which a hamming distance (branch metric) with the received encoded bits Rdata is smaller (BM=0), that is the maximum likelihood path which transmitted to node N1 is a path from the state bits 01.

As the node N4 of the state bits 00 at time t5 shows, the branch metric BM and path metric PM which is the accumulated value of the branch metrics BM to reach the node N4 from time t0 are shown on the top and bottom of each node where the value of the path metric PM is in parenthesis. In other words, BM (PM) is shown on the top and bottom of each node. Here the path metric PM is a cumulative sum of the smallest metric and branch metrics of the paths that could transit to this state. For example, the branch metrics BM of the node N3 of the state bits 00 at time t2 are 1 and 1, but one path metric PM of the node N3 is the cumulative sum (=1) of the smallest value “0” of the branch metrics BM (same as PM in the case of node N1) of the node N1 at the transition source (state bits 00 at time t1) and the branch metric BM=1 of the node N3, that is PM=1. The other path metric PM of the node N3 is the cumulative sum (=2) of the smallest value “1” of the branch metrics BM of the node N2 (state bits 01 at time t1) (BM on top and bottom are same value), and the branch metric BM=1 of the node N3, that is PM=2. Therefore BM (PM)=1(0), 1(2) are shown on the top and bottom of node N3. This is the same for the other nodes.

As described above, each time the encoded bits Rdata are received, the branch metric BM and the path metric PM of each state node can be computed. And even if the received encoded bits Rdata and transmitted encoded bits Tdata are different due to the noise generated in the transmission path, the maximum likelihood transition path can be detected and maximum likelihood input data can be decoded by selecting the transition path of which the hamming distance (metric) becomes the smallest.

In the case of the example in FIG. 5, the branch metric BM and the path metric PM are shown for all the state nodes until time t5. And comparing the path metrics PM of the four nodes at time t5, the node N5 corresponding to the state bits 10 has the smallest path metric PM=0. Therefore by selecting the node N5 for the start point of the trace back processing, maximum likelihood input data can be decoded. In the trellis diagram, a path of which path metric PM is smaller, out of the two paths which transit to each state, is called a “survival path”. In other words, by tracing the survival path of which the path metric PM is smaller from the node N5 which is the start point of the trace back processing, the most probable (maximum likelihood) transition path can be traced. In the case of the example in FIG. 5, trace back is performed from the state in node N5 to the state bits 00, to the state bits 00, to the state bits 01, and to the state bits 10, and finally to the state bits 00.

In the selection of the start point of the trace back processing, the final state bits can be defined to 00 by attaching a bit string, such as 000—known at the transmission side and the receive side, to the end of the input bits as the trail bits. In this way, if the final state bits are known, the node N4 of the state bits 00 is set to the start node of the trace back processing. By using the trail bits in this way, the influence of an error of the transmission path on the start bit can be avoided. By tracing the transition paths in this way, original input bits which caused each transition can be restored at high probability. If the trail bits are 111-, then the start node is the state bits 11.

As mentioned above, the branch metric BM and the path metric PM are computed for each node of the trellis diagram, and the transition branches of the smaller path metric are traced back with the node in final state as the start point, so the maximum likelihood state transition path in the encoder can be detected, and based on this, maximum likelihood original input data can be decoded. Storing all the information of the trellis diagram however makes the data capacity enormous, so this is not practical.

[Decoding Method of Japanese Patent Application Laid-Open No. H5-315976]

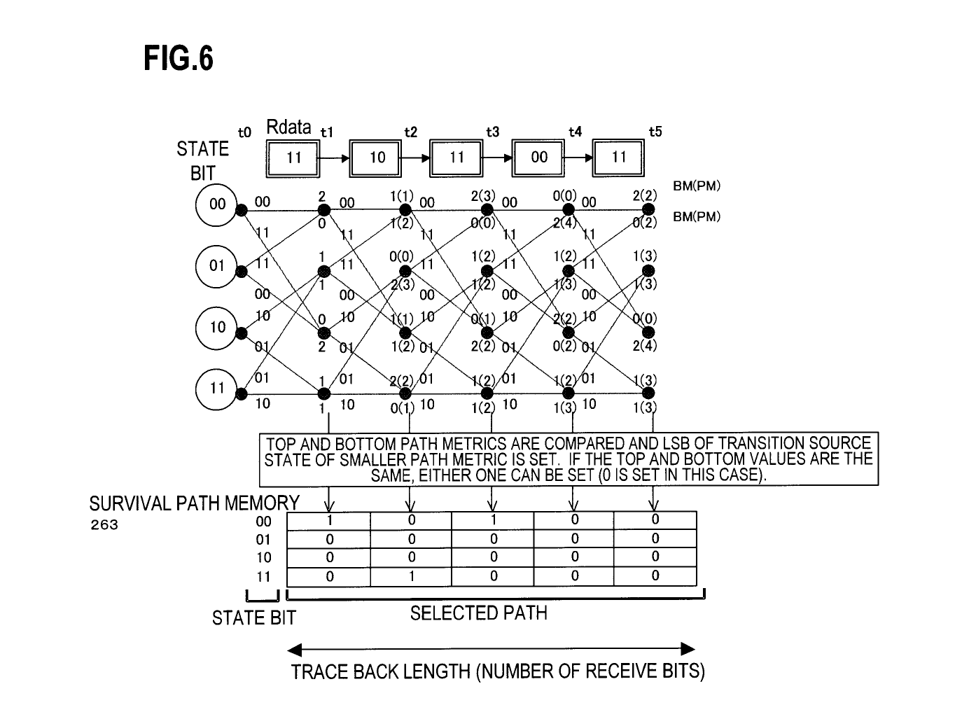

FIG. 6 is a diagram depicting the decoding method according to Japanese Patent Application Laid-Open No. H5-315976. According to this patent document (Japanese Patent Application Laid-Open No. H5-315976), the decoder stores the selected path information in the survival memory each time encoded bits are received, and performs trace back processing based on the selected path information in the survival memory after receiving encoded bits for the tracing length completes, and decodes the original input bits.

In the step of storing the selected path information to the survival memory, (1) the path metric values of the paths on the top and bottom of each state node are determined by adding the branch metric of this state node to the smaller path metric of the transition source, (2) the path metric values of the top and bottom input paths of each state node are compared, (3) the transition source state bits of which the path metric value is smaller are selected, and the least significant bit LSB of the transition source state bits is stored in the survival path memory 263 as the selected path information. If the path metric values are the same, either one of LSB (0 or 1) of the transition source state bits is stored. In the case of the example in FIG. 6, 0 is stored. In the case of four state nodes at time t5, for example, the LSBs of the transition source state bits of which path metric value is smaller are 0, 0, 0, 0 respectively. The LSBs of the transition source state bits at other times t4 to t1 are also stored in the same way.

As mentioned above, the selected path information to be stored in the survival path memory 263 for each state node is only 1 bit, LSB, so the memory capacity can be decreased.

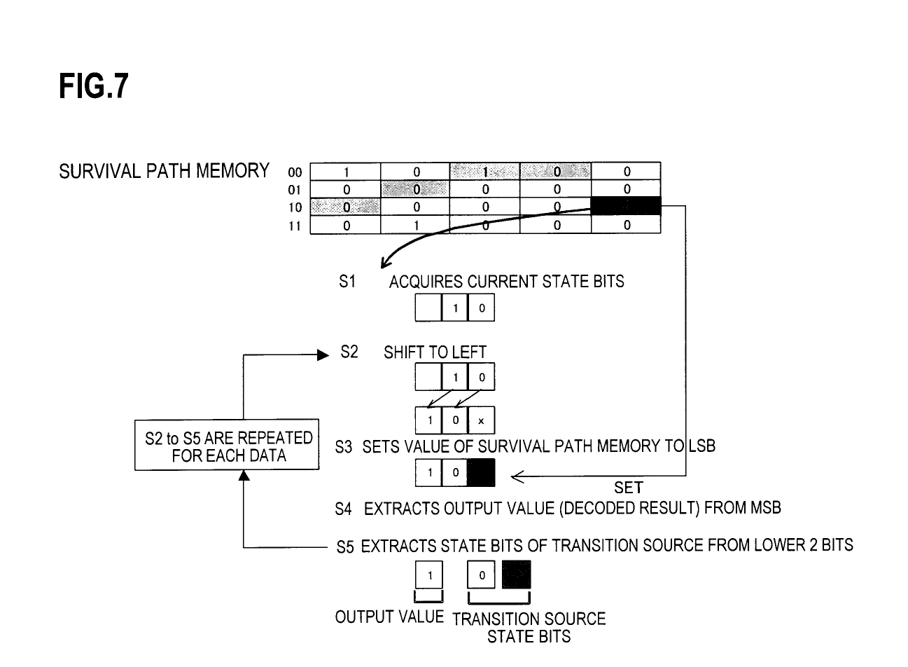

FIG. 7 is a diagram depicting the trace back processing. FIG. 7 shows an example when the start state node of the trace back processing is the node of the state bits 10. In the case of the trace back processing of this art, the state bits 10 at start are acquired as a variable (S1). And the state bits 10 are shifted to the left (S2). And the selected path information 0 in the survival path memory is input to the least significant bit of the variable shifted to the left (S3). And the decoding result 1 is extracted from the most significant bit MSB of the variable (S4). Then the lower 2 bits of the variable are extracted as the transition source state bits 00 (S5).

The above steps S2 to S5 are repeated for the total length of track back. The state transition paths to be traced by the trace back processing are shown by gray storage areas in the survival path memory in FIG. 7. As a result, 10001 is extracted as the decoded output value.

[Decoding Method of Present Embodiment]

In the present embodiment, the trace back processing of viterbi decoding is simplified so as to conform more to software processing. On the other hand, an increases in data volume of the selected path information to be stored in the survival path memory is tolerated. In other words, this decoding method focuses on simplifying software processing rather than memory capacity, since the price of memory recently is dropping.

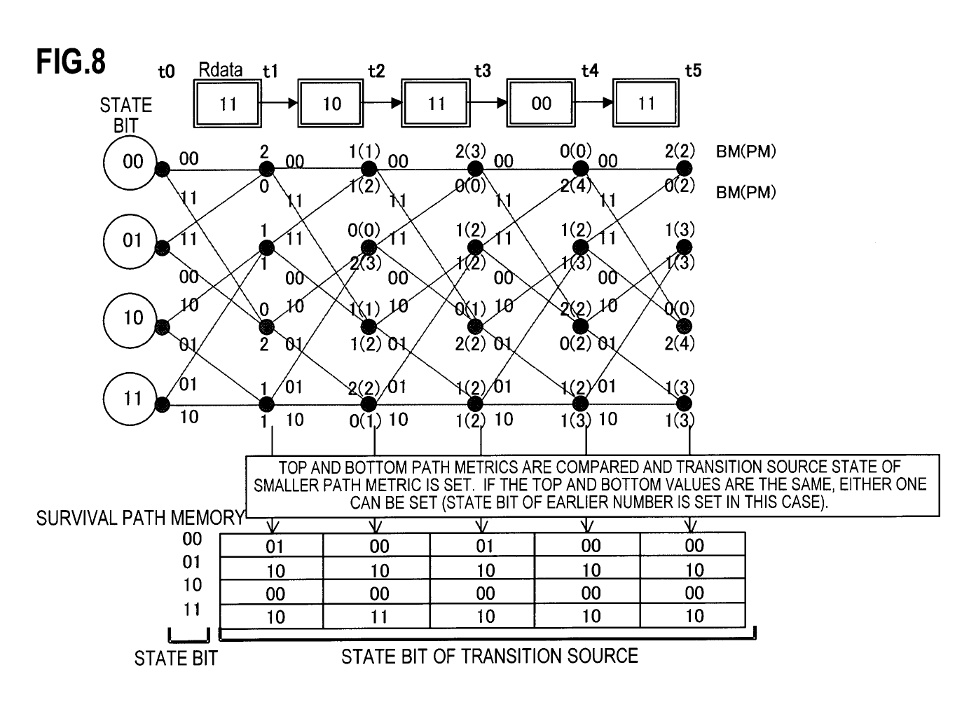

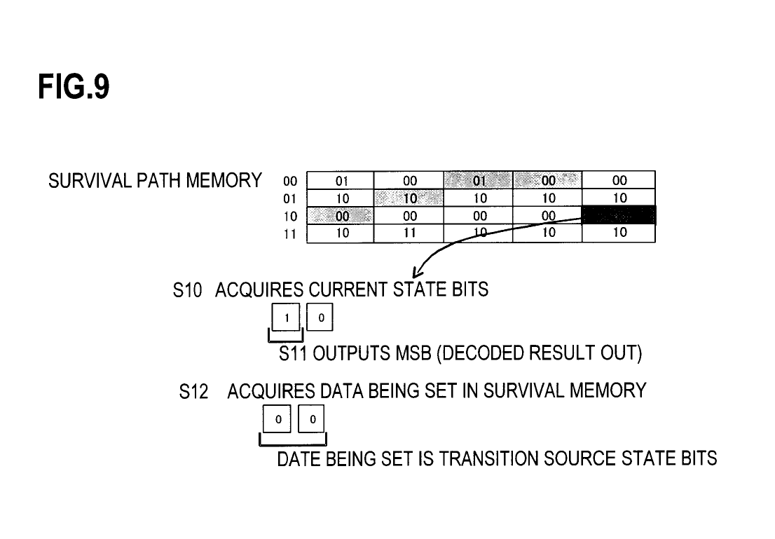

FIG. 8 and FIG. 9 are diagrams depicting the decoding method according to the present embodiment, and FIG. 8 shows the generation of the survival path memory and FIG. 9 shows the trace back processing. FIG. 8 shows the trellis diagram and received encoded bits Rdata, similar to FIG. 6. And each time encoded bits Rdata are received, the branch metric BM and path metric PM are computed according to each state bit, which is the same as Japanese Patent Application Laid-Open No. H5-315976. However the transition source state bits themselves selected by the select processing based on the comparison of the path metrics are stored in the survival path memory. This point is different from the above patent document. By this, track back processing can be simplified.

In the case of the example in FIG. 8, in the four state nodes that could take at time t5, the path metrics PM are the same for the state bits 00, so the transition source state bits 00, which are lower bits, are selected and stored. PMs are also the same for the state bits 01, so the transition source state bits 10, which are lower bits, are selected and stored. For the state bits 10, the transition source state bits 00, of which PM is lower, are selected and stored. And PMs are the same for the state bits 11, so the transition source state bits 10, which are lower bits, are selected and stored. For the other times t4 to t1 as well, the transition source state bits with a lower path metric based on the comparison of path metrics are selected and stored.

Each time the encoded bits Rdata are received, the branch metric BM and path metric PM are determined, and the transition source state bits of which the path metric is lower are selected and stored as the select path information in the survival path memory. It is, however, unnecessary to store the branch metrics BM and path metrics PM for all the times, but only the path metrics PM are updated.

When storing the select path information in the survival memory completes for the length of trace back, track back processing is executed. According to the present embodiment, the transition source state bits are directly stored in the survival path memory, so the trace back processing is simplified. In other words, as FIG. 9 shows, the state bits 10 of the trace start node are acquired (S10), and the most significant bit MSB of the state bits 10 is extracted as the decoded bit (S11). Then the selected path information (transition source state bit) stored in the survival memory is read (S12). The information is 00. Since this select path information 00, which was read, is the transition source state bits itself, the MSB thereof is extracted as the next decoded bit (S11). By repeating the processing S12 and S11, the state bits shown in gray in the survival path memory are traced.

As mentioned above, the trace back processing is merely reading the transition source state bits stored in the survival path memory and repeating the processing to extract the MSB thereof. Therefore software processing can be simplified. Since the normal convolutional encoder has a relatively long constraint length K, conformity to the information processing by software can be increased more if the constraint length is in byte units or word units.

Now an example of the viterbi decoder according to the present embodiment will be described.

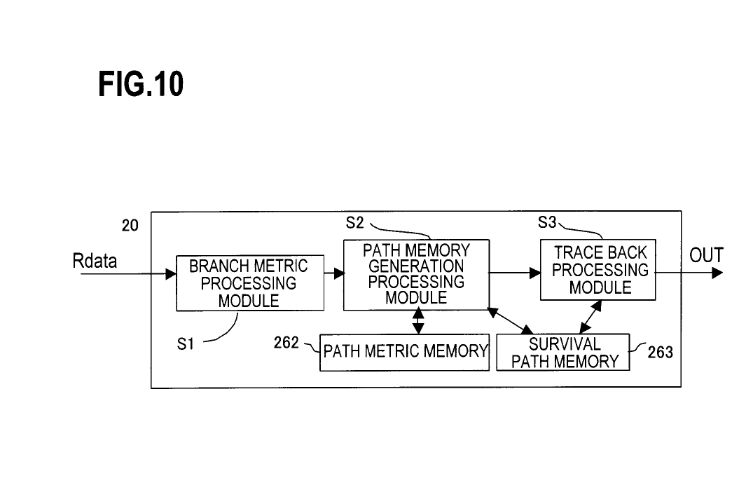

FIG. 10 is a diagram depicting the relationship between the processing modules and memories of the viterbi decoder according to the present embodiment. The hardware configuration of the viterbi decoder 20 comprises, as shown in FIG. 3, central processing unit CPU, decoding processing programs 22 and memories 26. And FIG. 10 shows the processing modules of the decoding processing program. The processing units are constructed by the viterbi decoding program having these processing modules installed on the computer.

As FIG. 10 shows, when the encoded bits Rdata are received, the branch metric processing module S1 determines the branch metrics BM corresponding to all the state bits. Specifically the hamming distance between the transmitted encoded bits Tdata and the received encoded bits Rdata is the branch metric, as mentioned above. And the determined branch metric BM is supplied to the path memory generation processing module S2. The path memory generation processing module S2 determines a new path metric by adding the supplied branch metric BM and the smaller one of the path metrics PM of the transition source state bits stored in the path metric memory 262, and stores the path metrics newly determined corresponding to the two transition source state bits in the path metric memory 262. And the transition source state bits corresponding to the smaller one of the determined path metrics are stored in the survival path memory 263.

And when storing the transition source state bits in the survival path memory for the length of the trace back ends, the trace back processing module S3 performs the trace back processing described in FIG. 9 based on the information in the survival path memory 263, and decodes the original input bits of the maximum likelihood source.

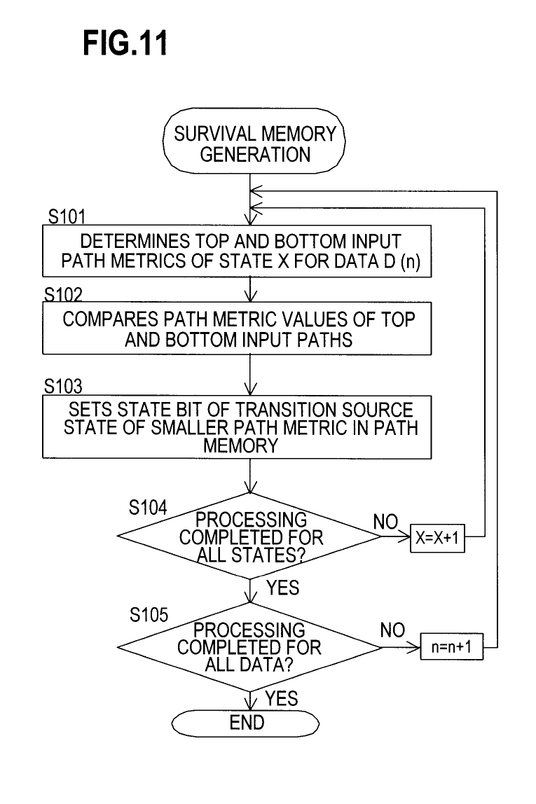

FIG. 11 is a flow chart depicting the processing of the path memory generation processing module. In this processing, the top and bottom path metrics PM of the state X with respect to the data D (n), which is received encoded bits, are determined (S101). And the path metrics of the top and bottom input paths are compared (S102). As a result of the comparison, the state bits of the transition source state of which path metric is smaller are stored in the survival path memory (S103). This processing is repeated for all the states (S104). The above processings S101 to S104 are also performed each time the encoded bits are received (S105). Or the survival path memory may be created by performing the processing in FIG. 11 for all the state nodes and all the received encoded bits of the trellis diagram after all of the encoded bits for the length of trace back are received. In this case however, the number of processing steps which are performed after completion of receiving the encoded bits increases. Therefore it is preferable that the processing to store the transition source state bits in the survival memory is performed each time encoded bits are received.

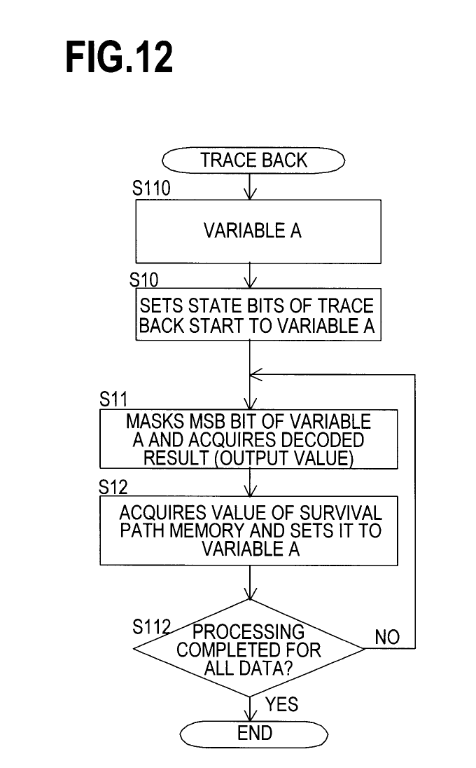

FIG. 12 is a flow chart depicting the trace back processing. First the variable A is defined (S110). This variable A is the 2-bit variable shown in FIG. 9, and in the case of the constraint length K=3, the number of bits of the variable A is K−1=2. And the state bits of the trace back start are set to the variable A (S10). Then the decoded result is acquired by extracting the MSB of the variable A (S11). And the transition source state bits stored in the survival path memory 263 corresponding to the state bits are read and set to the variable A (S12). And the decoding result is output by extracting the MSB of the transition source state bits being set to the variable A (S11). When the processings S12 and S11 are repeated for all the received encoded bits (S112), trace back processing completes.

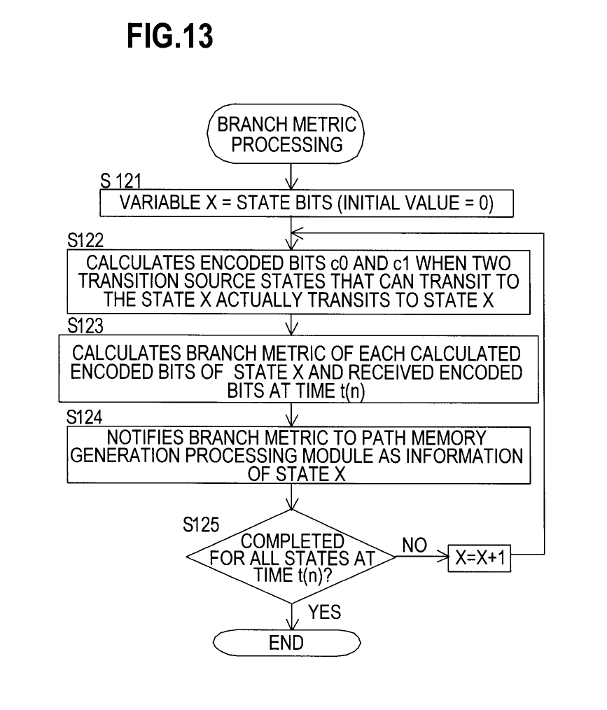

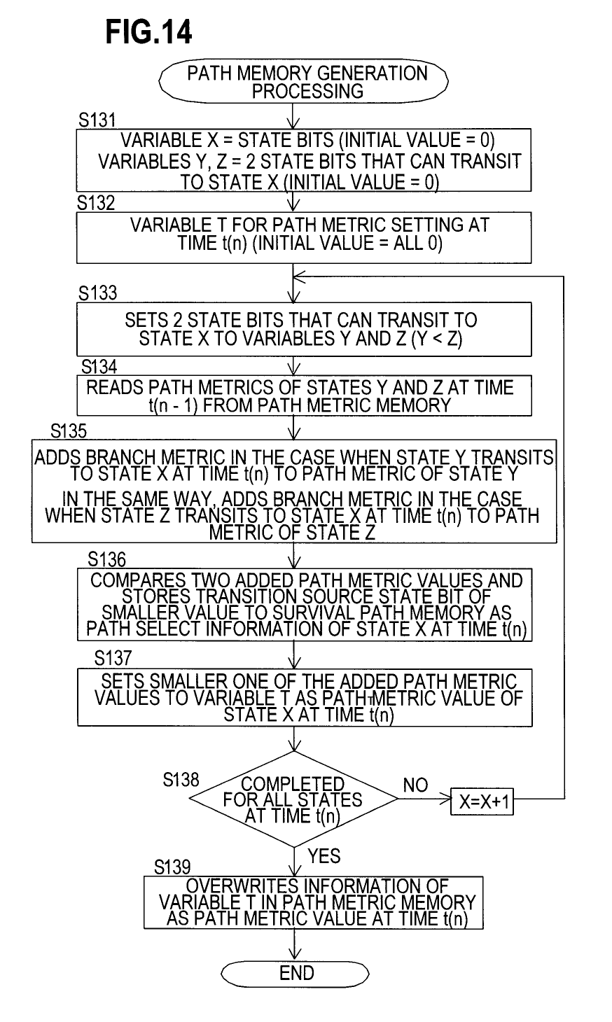

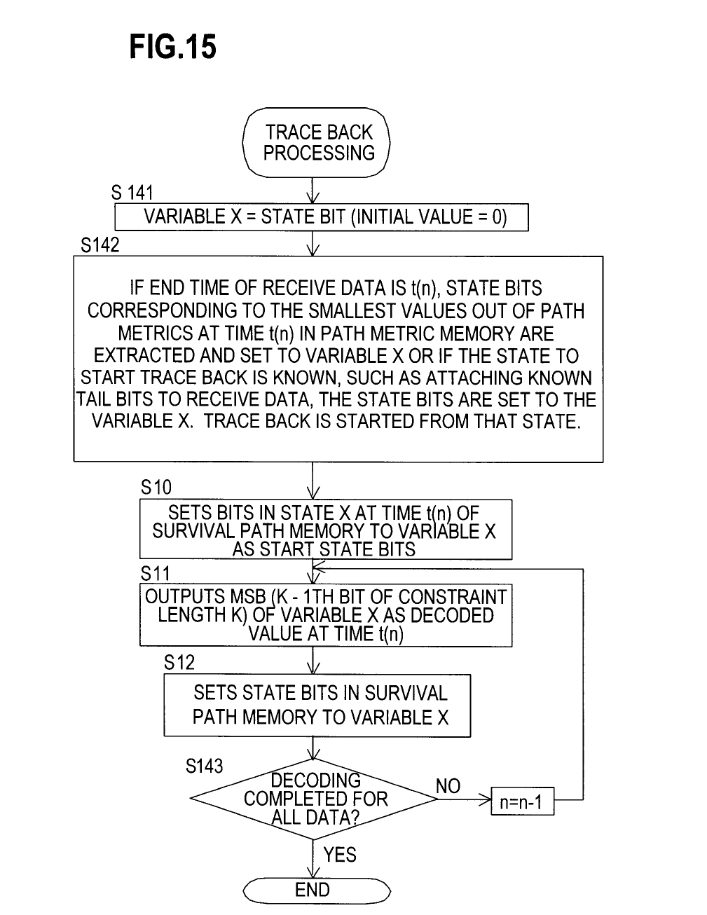

FIG. 13, FIG. 14 and FIG. 15 are flow charts depicting the specific processings of the processing modules of the viterbi decoder according to the present embodiment. The branch metric processing in FIG. 13 is executed each time the received encoded bits Rdata are input. It is assumed that the time of this reception is t(n). In this branch metric processing, first the state bits are set to the variable X (S121). The initial value is state bits 00. then the encoded bits c0 and c1, when the two transition source states that could transit to the state X, are determined (S122). These encoded bits c0 and c1 are bits which were convolutional-encoded from the transition source state bits and input bit. And the branch metric BM of the determined encoded bits corresponding to the state X and the received encoded bits at the time t(n) is calculated (S123). Finally the calculated branch metric BM is notified to the path memory generation processing module S2 as the information of the state X (S124). The above processing is repeated for all the states at the time t(n) (four states in the case of the example in FIG. 8) (S125).

The path memory generation processing in FIG. 14 is also executed each time the received encoded bits Rdata are input. First the variable X of the state bits and variables Y and Z of the two state bits that could transit to the state X (transition source state bits) are defined (S131). Also as the variable setting, the variable for path metric setting T at time t(n) is defined (S132).

The two state bits 00 and 01 that could transit to the state X of which the initial value is 00 are set to the variables Y and Z (S133). The two state bits Y and Z that could transit to the state X can be calculated by Y=2X and Y=2X+1 with respect to the state bits X. Assuming the 0^{th} bit is LSB and the constraint length is K, however, the K−1th bit of the calculated state bits must be 0. For example, if X=11, then Y=2X=110, and Z=2X+1=111, and if the K−1th bit is set to 0, Y=010 and Z=011, and the lower 2 bits can be calculated as the two state bits Y and Z that could transit to the state X.

And the path metrics of the states Y and Z at time t(n−1) are read from the path metric memory 262 (S134). To the path metric of the state Y=00, the branch metric in the case when the state Y transited to state X at time t(n) is added. In the same way, to the path metric of the state Z=01, the branch metric in the case when the state Z transited to state X at time t(n) is added (S135). The two path metric values acquired by the above addition are compared, and the transition source state bits of which the path metric value is smaller is stored in the survival path memory 263 as the path select information of the state X at time t(n) (S136). Also the smaller one of the two path metric values acquired by addition is set to the variable T as the path metric value at time t(n) (S137).

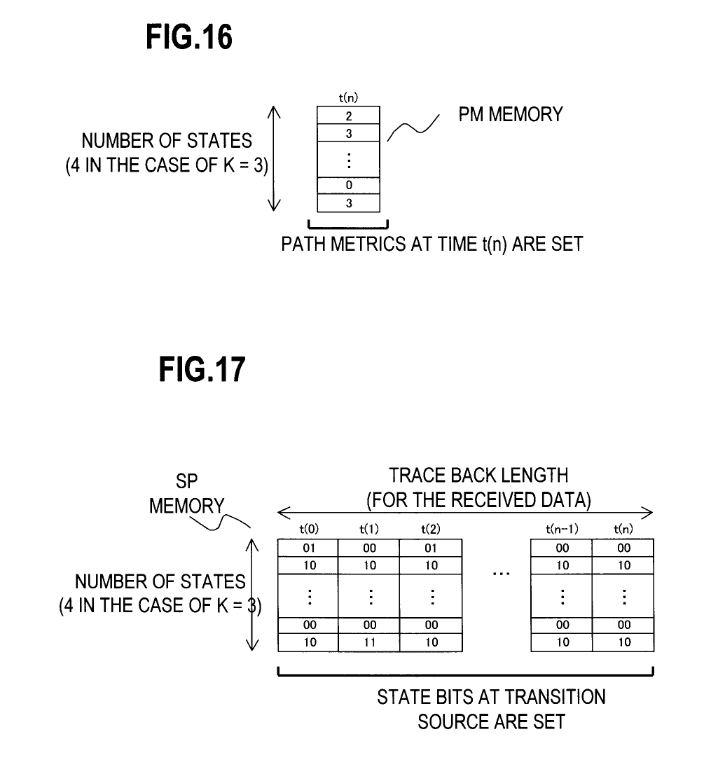

FIG. 16 is a diagram depicting an example of the path metric memory. In FIG. 16, the path metric PM memory having the elements for the number of states is shown. In other words, the path metric value at time t(n) is always updated and stored, so it is not necessary to store the path metric values at all the times.

The above processings S133 to S137 are repeated for all the states of time t(n). That is, at the next, the state X is set to 01, and Y=10 and Z=11 are set, the same processing is performed, and the path metric values are calculated, the transition source state bits of which path metric value is smaller are stored in the survival path memory, and the one of which path metric value is smaller is set to the variable T. Then the state X=10, Y=00 and Z=01 are set, and the same processing is performed. Finally the state X=11, Y=10 and Z=11 are set, and the same processing is performed. When the processing completes for all the states at time t(n), the path metric values which are set to the variable T in the end are overwritten to the path metric memory as the path metric values at time t(n) (S139).

FIG. 17 is a diagram depicting an example of the survival memory. The horizontal direction is time t(0) to t(n) corresponding to the trace back length, the vertical direction is state, and the transition source state bits are stored for each element. Therefore the survival path memory must store the selected path information required for track back in advance.

The trace back processing in FIG. 15 is executed after the processing in FIG. 13 and FIG. 14 completed for the length of trace back. In other words, after receiving of data blocks completes, trace back processing is performed. First the variable X, to indicate the state bits, is defined (S141). If the end time of the received data is t(n), the state bits corresponding to the smallest value of the path metric values at time t(n) in the path metric memory are extracted and set to variable X as the trace back start position (S142). If the state of starting trace back is already known, such as the case when a known tail bits are set between the transmission and receive sides, the state bits thereof are set to the variable X as the trace back start position (S142).

Then the bits of the state X at time t(n) in the survival path memory are set to the variable X as the start state bits (S10). The MSB of the variable X being set or the K−1th bit in the case of the constraint length K is output as the decoded bits at time t(n) (S11). The state bits stored corresponding to the state X in the survival path memory are overwritten to the variable X (S12). And the step S12 is performed for the variable X, and the next decoded bits are output (S11). The above steps S12 and S11 are repeated for all the received decoded bits, and maximum likelihood input bits are output in the sequence of t(n), t(n−1) . . . t(1), t(0) (S143).

As described above, the trace back processing becomes extremely simple software processing, by merely reading the transition source state bits stored in the survival path memory and outputting the MSB thereof as the decoding output. Therefore a dedicated hardware circuit is not necessary, and cost can be decreased.

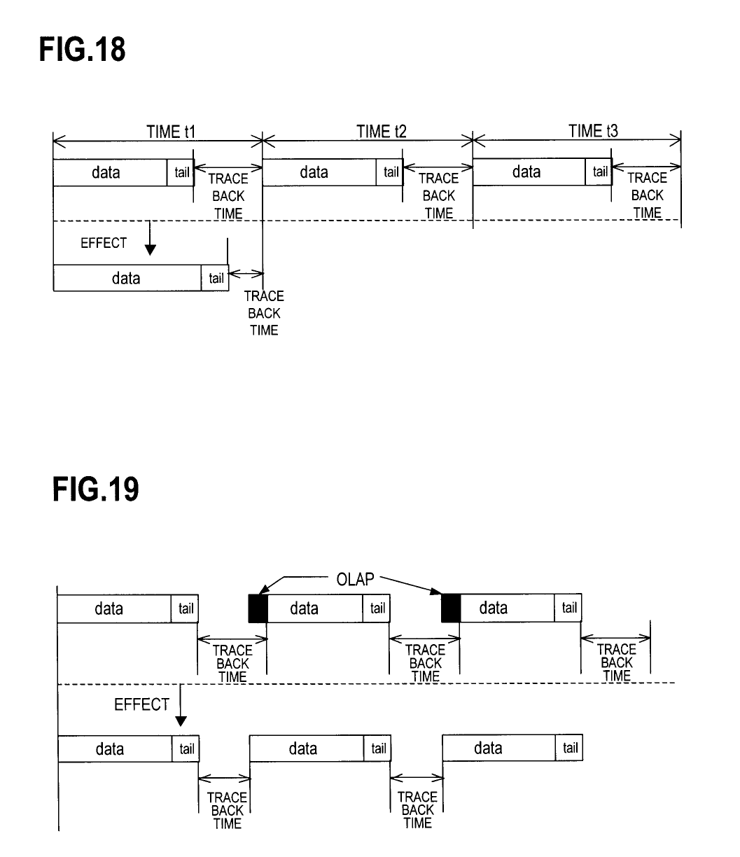

FIG. 18 is a diagram depicting the merit of operation of the viterbi decoder according to the present embodiment. The top section shows that the data block is transmitted at times t1, t2 and t3. The data block is comprised of the data string (data) of the input bits and the tail bit string (tail) which is attached at the end. In the case of the viterbi decoder of the present embodiment, track back processing is performed after receiving the encoded bit string corresponding to the data block completes. Also in the trace back processing, the transition source information bits are read from the survival path memory as the selected path information, so the decoding output and the transition source state bits to be traced back are included in the data which was read. Therefore extraction of the decoding result and trace back processing become simple. As a result, the trace back time can be decreased. This means that the number of data of the input bit string to be stored in the data block can be increased, the transmission data volume per unit time can be increased, and the transmission efficiency can be improved as shown at the bottom section in FIG. 18 shows.

FIG. 19 is a diagram depicting another merit of the viterbi decoder of the present embodiment. As the top section of FIG. 19 shows, in the base station which processes a plurality of user information all at once, the next data block may be received overlapping (OLAP in FIG. 19) before the trace back processing of the previous data block completes. Therefore two survival path memories are secured, one is the survival path memory for a previous data block, and the other is the survival path memory for a subsequent data block, for overlap. In the case of the viterbi decoder of the present embodiment however, the trace back processing is simplified and performed in a short time, so as shown at the bottom section in FIG. 19 shows, the overlap is cleared and decoding processing can be performed only by one survival memory.

What is claimed is:

1. A viterbi decoder for inputting encoded bits which are convolutional-encoded from state bits having input bit and a preceding (K−1) number of input bits, and decoding the input bit string by most likelihood encoding of the encoded bits, comprising:
a path memory generation processing unit which, for the encoded bits to be input, selects transition source state bits corresponding to predetermined state bits according to a path metric, and stores the transition source state bits in a survival path memory for each of a plurality of predetermined state bits that could be taken; and
a trace back processing unit which, after storing of the transition source state bits in the survival path memory for the encoded bits to be input ends for the length of the trace back, extracts the most significant bit of state bits to be a start point of trace back, repeats the extraction of the most significant bit of the transition source state bits in the survival path memory corresponding to the state bits of which the most significant bit has been extracted, and outputting the extracted most significant bits as a decoding result.

2. The viterbi decoder according to claim 1, wherein
the viterbi decoder receives the encoded bits sequentially,
the path memory generation processing unit stores the transition source state bits in the survival path memory each time the encoded bits are received, and
the trace back processing unit performs trace back processing after encoded bits for the length of the trace back are received.

3. The viterbi decoder according to claim 2, further comprising a branch metric processing unit which determines a branch metric of the encoded bits to be input and encoded bits corresponding to the transition source state bits, corresponding to the plurality of predetermined state bits that could be taken, wherein
the path memory generation processing unit determines the path metric of the predetermined state bits by adding the smallest path metric out of the path metrics of the transition source state bits to the determined branch metric, and selects the transition source state bits corresponding to the smallest path metric out of the determined path metrics.

4. The viterbi decoder according to claim 3, wherein the path memory generation processing unit determines the path metrics corresponding to all the state bits and updates the determined path metrics each time the encoded bits are received.

5. The viterbi decoder according to claim 1, wherein
the encoded bits to be input are encoded bits encoded from input bits having a predetermined bit length and subsequent tail bits having a predetermined bit length, and
the trace back processing unit sets the state bits corresponding to the tail bits as the trace start state bits.

6. The viterbi decoder according to claim 1, wherein the number of the plurality of predetermined state bits which could be taken is (K−1)th power of 2.

7. A viterbi decoding program for inputting encoded bits which are convolutional-encoded from state bits having input bit and a preceding (K−1) number of input bits, and decoding the input bit string by most likelihood encoding of the encoded bits, which causes a computer to construct:
a path memory generation processing unit which, for the encoded bits to be input, selects transition source state bits corresponding to predetermined state bits according to a path metric, and storing the transition source state bits in a survival path memory for each of a plurality of predetermined state bits that could be taken; and
a trace back processing unit which, after storing of the transition source state bits in the survival path memory for the encoded bits to be input ends for the length of the trace back,extracts the most significant bit of state bits to be a start point of trace back, repeats the extraction of the most significant bit of the transition source state bits in the survival path memory corresponding to the state bits of which the most significant bit has been extracted, and outputting the extracted most significant bits as a decoding result.

8. The viterbi decoding program according to claim 7, wherein
the encoded bits are received sequentially,
the path memory generation processing unit stores the transition source state bits in the survival path memory each time the encoded bits are received, and
the trace back processing unit performs trace back processing after encoded bits for the length of the trace back are received.

9. The viterbi decoding program according to claim 8, which causes a computer to construct a branch metric processing unit which determines a branch metric of the encoded bits to be input and encoded bits corresponding to the transition source state bits, corresponding to the plurality of predetermined state bits that could be taken, wherein
the path memory generation processing unit determines the path metric of the predetermined state bits by adding the smallest path metric out of the path metrics of the transition source state bits to the determined branch metric, and selects the transition source state bits corresponding to the smallest path metric out of the determined path metrics.

10. The viterbi decoding program according to claim 9, wherein the path memory generation processing unit determines the path metrics corresponding to all the state bits and updates the determined path metrics each time the encoded bits are received.

11. The viterbi decoding program according to claim 7, wherein
the encoded bits to be input are encoded bits encoded from input bits having a predetermined bit length and subsequent tail bits having a predetermined bit length, and
the trace back processing unit sets the state bits corresponding to the tail bits as the trace start state bits.
